(19) United States
(12) Patent Application Publication
(10) Pub. No.: US 2025/0079307 A1
(43) Pub. Date: Mar. 6, 2025

(54) SEMICONDUCTOR PACKAGING SUBSTRATE WITH INTERCONNECT UNITS BOUNDED BY DIELECTRIC FRAME

(71) Applicant: BRIDGE SEMICONDUCTOR CORP., Taipei City (TW)

(72) Inventors: Charles W. C. LIN, Singapore (SG); Chia-Chung WANG, Hsinchu County (TW)

(21) Appl. No.: 18/823,490

(22) Filed: Sep. 3, 2024

Related U.S. Application Data
(60) Provisional application No. 63/580,771, filed on Sep. 6, 2023.

(51) Int. Cl. H01L 23/528; H01L 23/495

(52) U.S. Cl. CPC H01L 23/5283; H01L 23/49568; H01L 23/49579

(57) ABSTRACT

A semiconductor packaging substrate comprises a crack-inhibiting dielectric frame and a plurality of interconnect units each including electrically conductive posts and an interfacial dielectric layer. These interconnect units are formed within separate compartments defined by the crack-inhibiting dielectric frame. The interfacial dielectric layer laterally covers and surrounds sidewalls of the electrically conductive posts. By using a crack-inhibiting dielectric frame instead of a conventional metal frame, structural warpage can be suppressed during the application of the interfacial dielectric layer.

### CROSS REFERENCE TO RELATED APPLICATION

This application claims the benefit of the filing date of U.S. Provisional Application Ser. No. 63/580,771 filed Sep. 6, 2023. The entirety of said Provisional Application is incorporated herein by reference.

### FIELD OF THE INVENTION

The present invention relates to a semiconductor packaging substrate and, more particularly, to a semiconductor packaging substrate with interconnect units bounded by a dielectric frame.

### DESCRIPTION OF RELATED ART

High-performance microprocessors and ASICs require substrates that offer high performance and reliability for signal interconnection. However, in conventional resin laminate substrates, the electroplated copper layer is prone to peeling under stringent operational conditions, making these substrates unreliable for practical use. In specific applications, ceramic materials like alumina or aluminum nitride are preferred for their desirable attributes, including excellent electrical insulation, robust mechanical strength, low coefficient of thermal expansion (CTE), and efficient thermal conductivity. Consequently, multi-layer ceramic substrates, such as HTCC (high temperature co-fired ceramic) or LTCC (low temperature co-fired ceramic), have been developed to meet specific application demands.

In addition to the resin laminate substrates and the multi-layer ceramic substrates mentioned above, copper lead frame substrates have emerged as another favored option. They offer distinct advantages such as high thermal conductivity, excellent electrical properties, and straightforward manufacturing processes. However, there remains a critical need for further improvement to address issues such as warpage, cracking, and other related problems. This pursuit of enhancement is pivotal in ensuring the continued advancement and reliability of high-performance semiconductor devices.

### SUMMARY OF THE INVENTION

An objective of the present invention is to provide an innovative semiconductor packaging substrate featuring a crack-inhibiting dielectric frame, as opposed to the metal frame in the conventional copper lead frame substrate, to define multiple compartments, each of which accommodates an interconnect unit. In manufacturing of the semiconductor packaging substrate, compared to the conventional metal frame, the crack-inhibiting dielectric frame can reduce warpage caused by the subsequent application of an interfacial dielectric layer and enhance the substrate's reliability.

In accordance with the foregoing and other objectives, the present invention provides a semiconductor packaging substrate that includes a crack-inhibiting dielectric frame and a plurality of interconnect units each disposed within a respective one of separate compartments defined by the crack-inhibiting dielectric frame. Each of the interconnect units includes electrically conductive posts and an interfacial dielectric layer. The crack-inhibiting dielectric frame has a plurality of inner peripheries each laterally surrounding a respective one of the interconnect units. The electrically conductive posts are disposed within the compartments and spaced from each other by the interfacial dielectric layer. The interfacial dielectric layer laterally covers and surrounds sidewalls of the electrically conductive posts and coats the inner peripheries of the crack-inhibiting dielectric frame.

The semiconductor packaging substrate can further include a thermal pad, and the interfacial dielectric layer laterally covers and surrounds sidewalls of the thermal pad. Accordingly, the present invention can provide an assembly in which a semiconductor device is superimposed over and thermally conductible with the thermal pad and electrically connected to the electrically conductive posts of the semiconductor packaging substrate through wires.

These and other features and advantages of the present invention will be further described and more readily apparent from the detailed description of the preferred embodiments which follows.

### BRIEF DESCRIPTION OF THE DRAWINGS

The detailed description of the preferred embodiments of the present invention can best be understood when read in conjunction with the following drawings, in which:

FIG. 1 is a cross-sectional view of an electrically and thermally conductive plate in accordance with the first embodiment of the present invention;

FIGS. 2 and 3 are cross-sectional and top perspective views, respectively, of the structure of FIG. 1 further provided with a crack-inhibiting dielectric frame in accordance with the first embodiment of the present invention;

FIGS. 4 and 5 are cross-sectional and top perspective views, respectively, of the structure of FIGS. 2 and 3 further provided with an interfacial dielectric layer in accordance with the first embodiment of the present invention;

FIGS. 6 and 7 are cross-sectional and bottom perspective views, respectively, of the structure of FIGS. 4 and 5 further formed with electrically conductive posts and thermal pads to finish the fabrication of a semiconductor packaging substrate in accordance with the first embodiment of the present invention;

FIG. 8 is a cross-sectional view of the structure of FIG. 6 further provided with semiconductor devices in accordance with the first embodiment of the present invention;

FIG. 9 is a cross-sectional view of the structure of FIG. 8 further provided with a sealant in accordance with the first embodiment of the present invention;

FIGS. 10 and 11 are cross-sectional and top perspective views, respectively, of the structure of FIG. 9 diced into singulated units in accordance with the first embodiment of the present invention;

FIG. 12 is a cross-sectional view of an individual singulated semiconductor assembly in accordance with the first embodiment of the present invention;

FIG. 13 is a cross-sectional view of another aspect of the semiconductor assembly in accordance with the first embodiment of the present invention;

FIG. 14 is a cross-sectional view of a semiconductor packaging substrate in accordance with the second embodiment of the present invention;

FIG. 15 is a cross-sectional view of the structure of FIG. 14 further provided with semiconductor devices and a sealant in accordance with the second embodiment of the present invention;

FIG. 16 is a cross-sectional view of a semiconductor assembly singulated from the structure of FIG. 15 in accordance with the second embodiment of the present invention;

FIG. 17 is a cross-sectional view of a cross-sectional view of a semiconductor packaging substrate in accordance with the third embodiment of the present invention.

FIG. 18 is a cross-sectional view of the structure of FIG. 17 further provided with semiconductor devices and a sealant in accordance with the third embodiment of the present invention;

FIG. 19 is a cross-sectional view of a semiconductor assembly singulated from the structure of FIG. 18 in accordance with the third embodiment of the present invention;

FIGS. 20 and 21 are cross-sectional and top perspective views, respectively, of the structure with a patterned conductive layer formed on a sacrificial carrier in accordance with the fourth embodiment of the present invention;

FIG. 22 is a cross-sectional view of the structure of FIG. 20 further provided with an array of protrusions in accordance with the fourth embodiment of the present invention;

FIGS. 23 and 24 are cross-sectional and top perspective views, respectively, of the structure of FIG. 22 further provided with a crack-inhibiting dielectric frame in accordance with the fourth embodiment of the present invention;

FIGS. 25 and 26 are cross-sectional and top perspective views, respectively, of the structure of FIGS. 23 and 24 further provided with an interfacial dielectric layer in accordance with the fourth embodiment of the present invention;

FIGS. 27 and 28 are cross-sectional and bottom perspective views, respectively, of the structure of FIGS. 25 and 26 subjected to removal of the sacrificial carrier to finish the fabrication of a semiconductor packaging substrate in accordance with the fourth embodiment of the present invention;

FIG. 29 is a cross-sectional view of a semiconductor packaging substrate combined with a sacrificial carrier in accordance with the fifth embodiment of the present invention;

FIG. 30 is a cross-sectional view of the structure of FIG. 29 subjected to removal of the sacrificial carrier to finish the fabrication of a semiconductor packaging substrate in accordance with the fifth embodiment of the present invention;

FIG. 31 is a cross-sectional view of a semiconductor packaging substrate in accordance with the sixth embodiment of the present invention.

FIG. 32 is a cross-sectional view of the structure of FIG. 31 further provided with semiconductor devices and a sealant in accordance with the sixth embodiment of the present invention;

FIG. 33 is a cross-sectional view of a semiconductor assembly singulated from the structure of FIG. 32 in accordance with the sixth embodiment of the present invention;

FIG. 34 is a cross-sectional view of a semiconductor packaging substrate combined with a sacrificial carrier in accordance with the seventh embodiment of the present invention;

FIG. 35 is a cross-sectional view of the structure of FIG. 34 subjected to removal of the sacrificial carrier to finish the fabrication of a semiconductor packaging substrate in accordance with the seventh embodiment of the present invention;

FIG. 36 is a cross-sectional view of another aspect of the semiconductor packaging substrate in accordance with the seventh embodiment of the present invention;

FIG. 37 is a cross-sectional view of yet another aspect of the semiconductor packaging substrate in accordance with the seventh embodiment of the present invention.

### DETAILED DESCRIPTION OF THE PREFERRED EMBODIMENTS

Hereafter, examples will be provided to illustrate the embodiments of the present invention. The advantages and effects of the invention will become more apparent from the following description of the present invention. It should be noted that the accompanying figures are simplified and illustrative. The quantity, shape and size of components shown in the figures may be modified according to practical conditions, and the arrangement of components may be more complex. Other various aspects may also be practiced or applied in the invention, and various modifications and variations can be made without departing from the spirit of the invention based on various concepts and applications.

### Embodiment 1

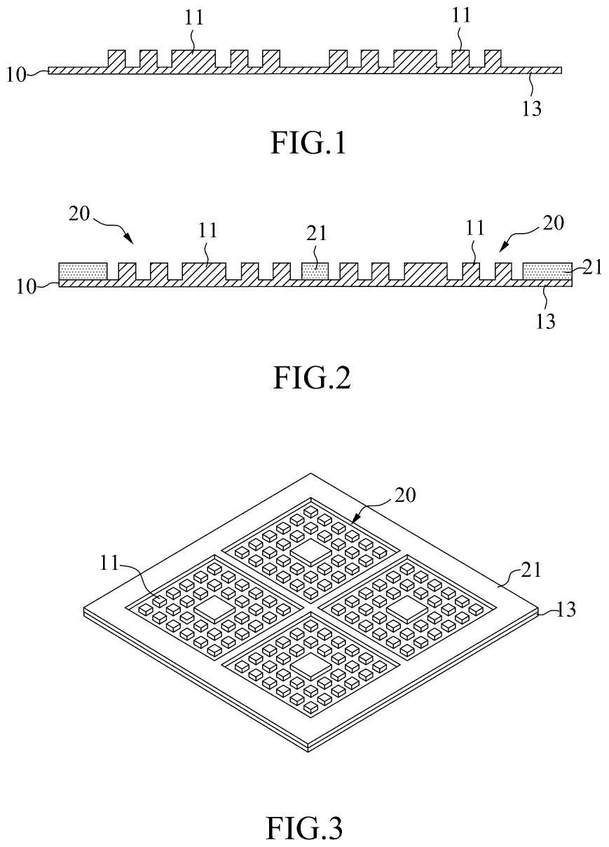

FIGS. 1-9 are schematic views showing a method of making a un-singulated assembly in which each of semiconductor devices is electrically connected to a respective one of interconnect units of a semiconductor packaging substrate and the interconnect units are spaced from each other by a crack-inhibiting dielectric frame of the semiconductor packaging substrate in accordance with the first embodiment of the present invention.

FIG. 1 is a cross-sectional view of an electrically and thermally conductive plate 10 formed with an array of protrusions 11 projecting from a base 13 by, for example, one-sided etching or plating. The electrically and thermally conductive plate 10 can have a thickness (namely, a combined thickness of the protrusion 11 and the base 13) ranging from, for example, 0.15 mm to 0.3 mm, and typically is made of copper, aluminum, alloy 42, iron, nickel, silver, gold, combinations thereof, alloys thereof or any other suitable metals. In this embodiment, the electrically and thermally conductive plate 10 is made of copper with a thickness of about 0.25 mm, and the thickness of the base 13 is illustrated as 50 micrometers.

FIGS. 2 and 3 are cross-sectional and top perspective views, respectively, of the structure provided with a crack-inhibiting dielectric frame 21. The crack-inhibiting dielectric frame 21 may have an elastic modulus lower than 50 Gpa and is deposited and attached on the base 13 from above to define a plurality of separate compartments 20. The compartments 20 can be arranged into an N×M array, such as a 2×2 array in this embodiment, and these protrusions 11 are present in the same quantity and arrangement within every compartment 20. Preferably, the crack-inhibiting dielectric frame 21 contains reinforcement to enhance the functionality of suppressing crack propagation through the crack-inhibiting dielectric frame 21. For instance, the crack-inhibiting dielectric frame 21 may be made of an organic material (such as epoxy-based material) with glass reinforcement (such as fiberglass). In this illustration, the top surface of the crack-inhibiting dielectric frame 21 is substantially coplanar with the top sides of the protrusions 11.

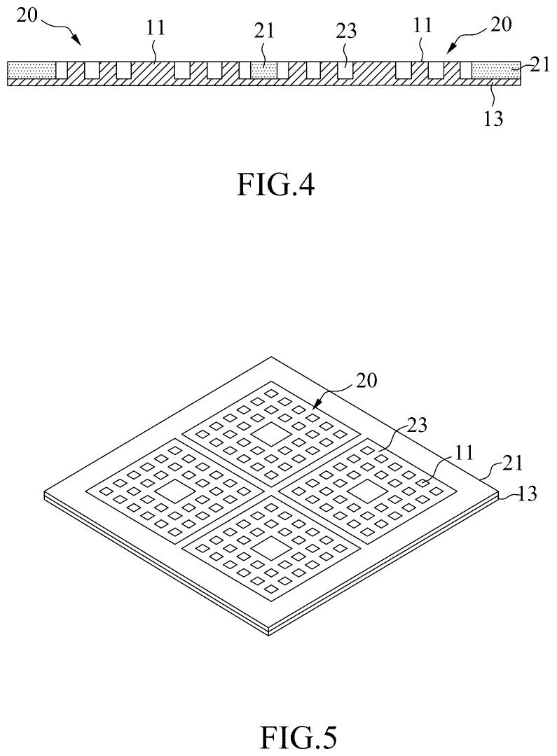

FIGS. 4 and 5 are cross-sectional and top perspective views, respectively, of the structure provided with an interfacial dielectric layer 23. The interfacial dielectric layer 23 is filled into remaining spaces within the compartments 20 to cover sidewalls of the protrusions 11 and the top surface of the base 13 and inner peripheries of the crack-inhibiting dielectric frame 21. By the crack-inhibiting dielectric frame 21 with an elastic modulus lower than 50 Gpa instead of a conventionally used metal frame, the structural warpage due to the dispensation of the interfacial dielectric layer 23 can be suppressed. In some instances, the interfacial dielectric layer 23 may have an elastic modulus lower than that of the crack-inhibiting dielectric frame 21 to absorb stress and thus further alleviate warpage. Additionally, the interfacial dielectric layer 23 may contain electrically insulative fillers with a coefficient of thermal expansion (CTE) less than 20 ppm dispersed in an organic material (such as epoxy-based material) for alleviating internal expansion and shrinkage of the interfacial dielectric layer 23 during thermal cycling. In this illustration, the top surface of the interfacial dielectric layer 23 is substantially coplanar with the top sides of the protrusions 11 and the top surface of the crack-inhibiting dielectric frame 21.

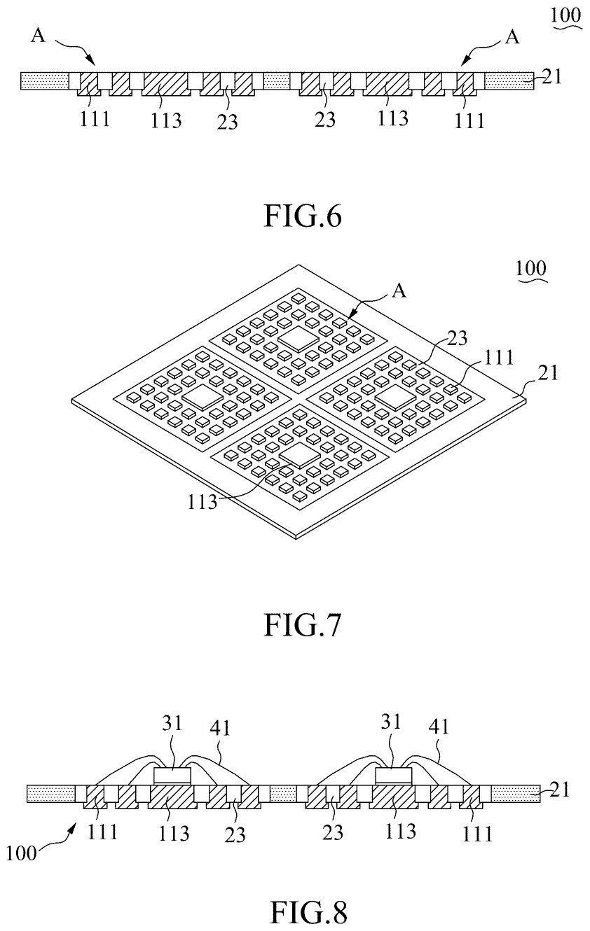

FIGS. 6 and 7 are cross-sectional and bottom perspective views, respectively, of the structure formed with electrically conductive posts 111 and optional thermal pads 113. The base 13 of the electrically and thermally conductive plate 10 is patterned by, for example, etching, to leave selected portions of the base 13 each integrated with a respective one of the protrusions 11, thereby forming the electrically conductive posts 111 for vertical electrical connection and the optional thermal pads 113 for device attachment. The metal patterning techniques include wet etching, electro-chemical etching, laser-assisted etching, and their combinations with etch masks (not shown) thereon. The electrically conductive posts 111 and the thermal pads 113 are spaced from each other by the interfacial dielectric layer 23 and each have upper portion laterally covered and surrounded by the interfacial dielectric layer 23 and a lower portion extending laterally below the bottom surface of the interfacial dielectric layer 23.

Accordingly, a semiconductor packaging substrate 100 is accomplished and includes multiple interconnect units A and the crack-inhibiting dielectric frame 21. Each of the interconnect units A is disposed within a respective one of separate compartments 20 defined by the crack-inhibiting dielectric frame 21, and includes the electrically conductive posts 111, the thermal pad 113, and the interfacial dielectric layer 23.

FIG. 8 is a cross-sectional view of the structure provided with semiconductor devices 31 attached to the semiconductor packaging substrate 100 illustrated in FIG. 6. Each of the semiconductor devices 31, illustrated as chips, is mounted and superimposed over a respective one of the thermal pads 113 by a thermal adhesive from above and electrically coupled to respective ones of the electrically conductive posts 111 using wires 41.

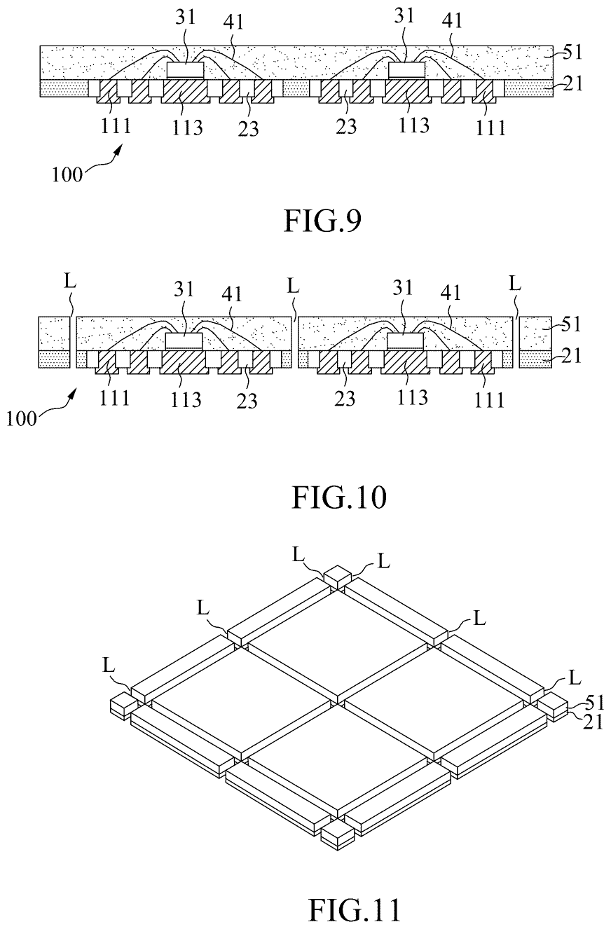

FIG. 9 is a cross-sectional view of the structure optionally provided with a sealant 51. The sealant 51 encapsulates the semiconductor devices 31 and the wires 41 and covers the electrically conductive posts 111, the thermal pads 113, the crack-inhibiting dielectric frame 21 and the interfacial dielectric layer 23 from above, and extends laterally to outer peripheral edges of the crack-inhibiting dielectric frame 21.

At this stage, a un-singulated assembly is accomplished and includes the semiconductor packaging substrate 100, the semiconductor devices 31 electrically connected to the semiconductor packaging substrate 100 via the wires 41, and the sealant 51 encapsulating the semiconductor devices 31.

FIGS. 10 and 11 are cross-sectional and top perspective views, respectively, of the structure diced into singulated units. The un-singulated assembly is divided into individual units along dicing lines “L” by cutting through the sealant 51 and the crack-inhibiting dielectric frame 21.

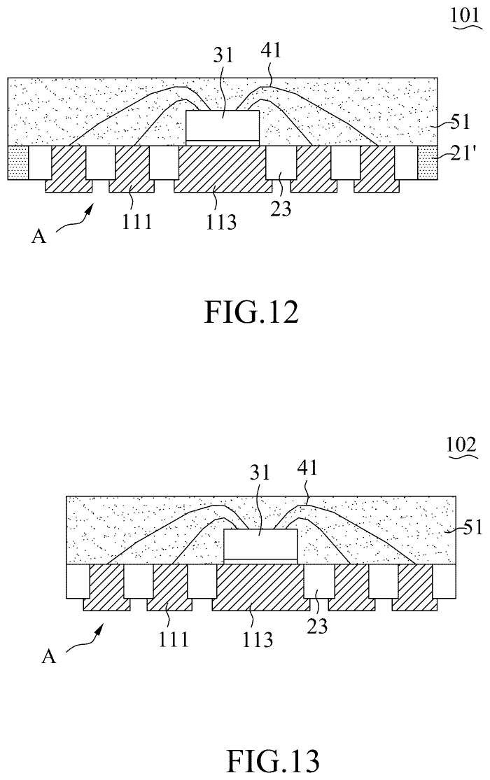

FIG. 12 is a cross-sectional view of the individual singulated semiconductor assembly 101. In this illustration, the semiconductor assembly 101 includes an interconnect unit A, a crack-inhibiting dielectric sub-frame 21′, a semiconductor device 31, wires 41 and a sealant 51. The interconnect unit A includes electrically conductive posts 111, a thermal pad 113 and an interfacial dielectric layer 23. The crack-inhibiting dielectric sub-frame 21′ is singulated from the crack-inhibiting dielectric frame 21 and located all around the interconnect unit A. The electrically conductive posts 111 are spaced from each other and the crack-inhibiting dielectric sub-frame 21′ by the interfacial dielectric layer 23. The interfacial dielectric layer 23 laterally covers and surrounds sidewalls of the electrically conductive posts 111 and the inner periphery of the crack-inhibiting dielectric sub-frame 21′. The semiconductor device 31 is thermally conductible with the thermal pad 113 by a thermal adhesive and electrically connected to the electrically conductive posts 111 via the wires 41. The sealant 51 encapsulates the semiconductor device 31 and extends laterally to an outer periphery of the crack-inhibiting dielectric sub-frame 21′.

FIG. 13 is a cross-sectional view of another aspect of the semiconductor assembly in accordance with the first embodiment of the present invention. The semiconductor assembly 102 is similar to that illustrated in FIG. 12, except that the crack-inhibiting dielectric frame 21 is removed entirely in the singulation process. Thereby, the ultimate semiconductor assembly 102 is devoid of any singulated crack-inhibiting dielectric frame, and the interfacial dielectric layer 23 and the sealant 51 extend laterally to the periphery of the semiconductor assembly 102.

### Embodiment 2

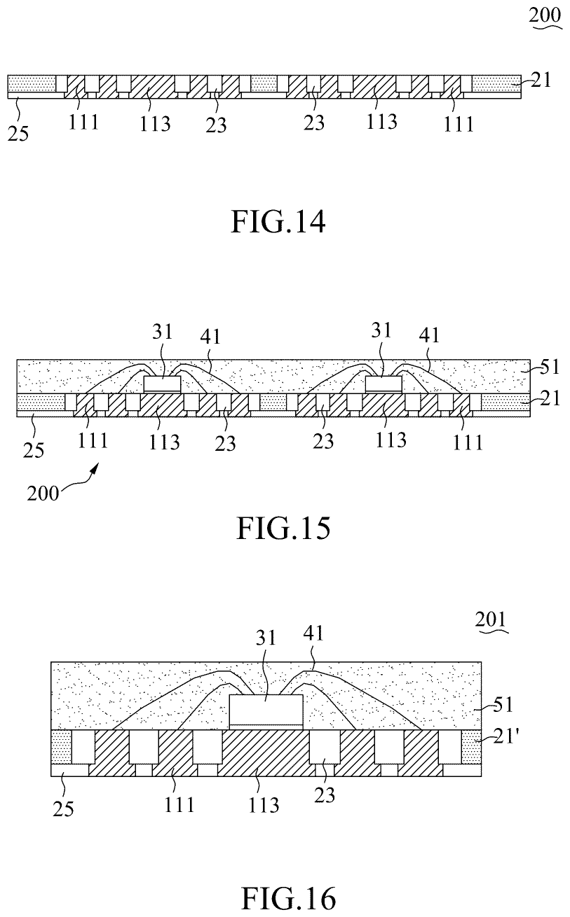

FIGS. 14-15 are schematic views showing a method of making a un-singulated assembly in accordance with the second embodiment of the present invention. For purposes of brevity, any description in above Embodiment 1 is incorporated herein insofar as the same is applicable, and the same description need not be repeated.

FIG. 14 is a cross-sectional view of a semiconductor packaging substrate 200 in accordance with the second embodiment of the present invention. The semiconductor packaging substrate 200 is similar to that illustrated in FIG. 6, except that an external dielectric layer 25 is further provided and covers the crack-inhibiting dielectric frame 21 and the interfacial dielectric layer 23 from below and has a bottom surface substantially coplanar with the bottom sides of the electrically conductive posts 111 and the thermal pads 113.

FIG. 15 is a cross-sectional view of the structure provided with semiconductor devices 31 wire bonded to the semiconductor packaging substrate 200 illustrated in FIG. 14 and optionally with a sealant 51 for encapsulation. The semiconductor devices 31 are electrically connected to the semiconductor packaging substrate 200 via wires 41 and encapsulated by the sealant 51.

FIG. 16 is a cross-sectional view of a semiconductor assembly 201 singulated from the un-singulated assembly of FIG. 15. The semiconductor assembly 201 includes a crack-inhibiting dielectric sub-frame 21′, electrically conductive posts 111, a thermal pad 113, an interfacial dielectric layer 23, an external dielectric layer 25, a semiconductor device 31, wires 41 and a sealant 51.

### Embodiment 3

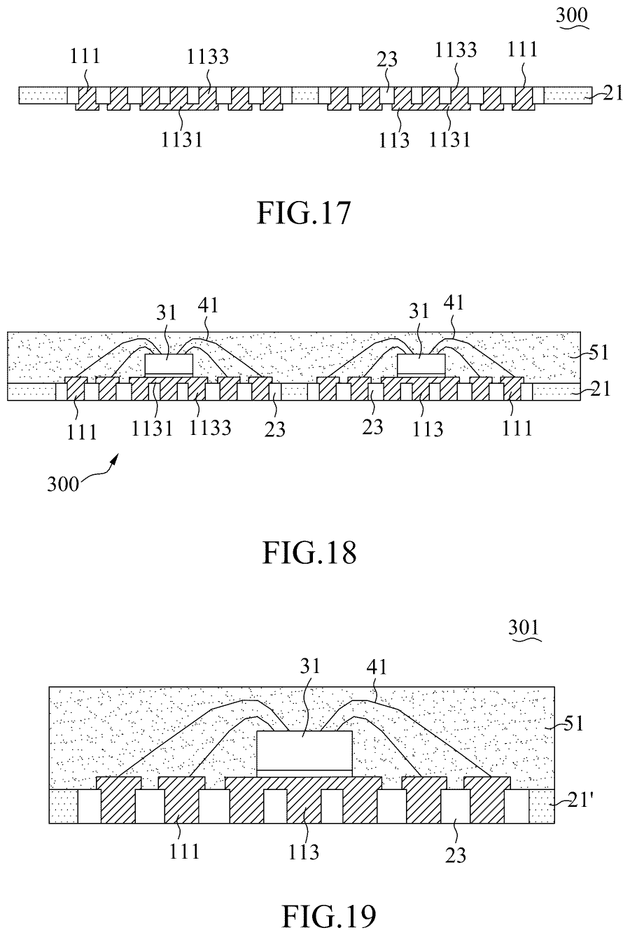

FIGS. 17-18 are schematic views showing a method of making a un-singulated assembly in accordance with the third embodiment of the present invention. For purposes of brevity, any description in above Embodiments is incorporated herein insofar as the same is applicable, and the same description need not be repeated.

FIG. 17 is a cross-sectional view of a semiconductor packaging substrate 300 in accordance with the third embodiment of the present invention. The semiconductor packaging substrate 300 is similar to that illustrated in FIG. 6, except that the each of the thermal pads 113 has a foundation 1131 and pin fins 1133 protruding from the foundation 1131 and spaced from each other by gaps filled with the interfacial dielectric layer 23 which laterally covers and surrounds sidewalls of the pin fins 1133. The foundation 1131 laterally extends below the bottom surface of the interfacial dielectric layer 23 and typically has a bottom side substantially coplanar with bottom sides of the electrically conductive posts 111. Each of the pin fins 1133 has a proximal end adjacent to the foundation 1131 and a distal end opposite to the proximal end and substantially coplanar with the top side of each of the electrically conductive posts 111. Preferably, the distal end of each of the pin fins 1133 and the top side of each of the electrically conductive posts 111 have the same exposed surface area to ensure that soldering balls subsequently attached to the distal ends of the pin fins 1133 and the top sides of the electrically conductive posts 111 have the same height and thus to avoid false soldering.

FIG. 18 is a cross-sectional view of a cross-sectional view of the structure provided with semiconductor devices 31 coupled to the semiconductor packaging substrate 300 illustrated in FIG. 17 and optionally with a sealant 51 for encapsulation. In this illustration, the semiconductor packaging substrate 300 is inverted, and each of the semiconductor devices 31 is attached to the foundation 1131 of the respective thermal pad 113 by a thermal adhesive and electrically connected to the electrically conductive posts 111 via wires 41 and encapsulated by the sealant 51.

FIG. 19 is a cross-sectional view of a semiconductor assembly 301 singulated from the un-singulated assembly of FIG. 18. The semiconductor assembly 301 includes a crack-inhibiting dielectric sub-frame 21′, electrically conductive posts 111, a thermal pad 113, an interfacial dielectric layer 23, a semiconductor device 31, wires 41 and a sealant 51.

### Embodiment 4

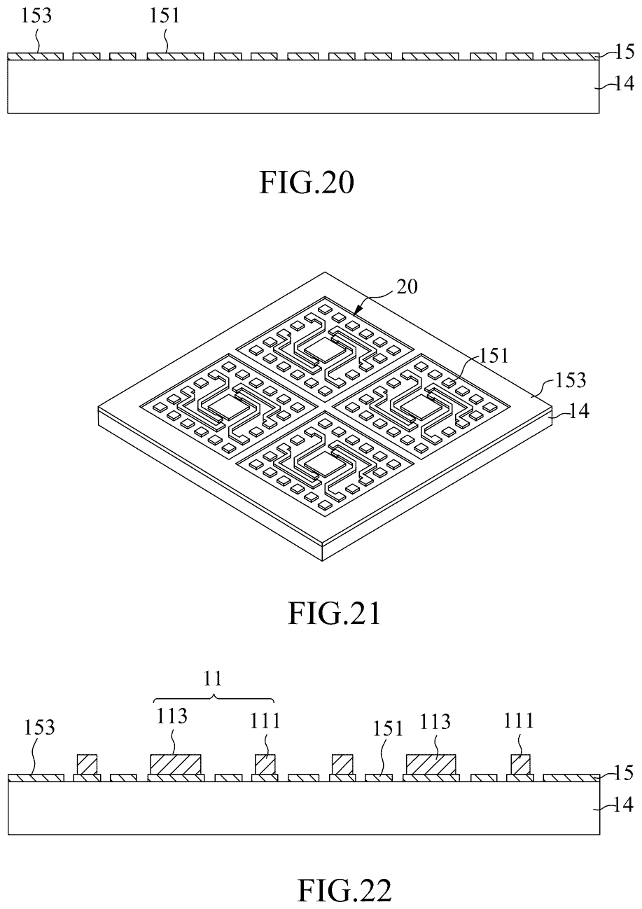

FIGS. 20-28 are schematic views showing a method of making a semiconductor packaging substrate in accordance with the fourth embodiment of the present invention. For purposes of brevity, any description in above Embodiments is incorporated herein insofar as the same is applicable, and the same description need not be repeated.

FIGS. 20 and 21 are cross-sectional and top perspective views, respectively, of the structure with a patterned conductive layer 15 formed on a sacrificial carrier 14. The patterned conductive layer 15 typically is made of copper, aluminum, alloy 42, iron, nickel, silver, gold, combinations thereof, alloys thereof or any other suitable metals, and can be deposited on the sacrificial carrier 14 by, for example, electrolytic plating. The patterned conductive layer 15 includes a trace portion 151 and a frame portion 153. The frame portion 153 can define an N×M array (such as a 2×2 array as shown in this embodiment) of compartments 20. The trace portion 151 typically has the same trace pattern in every compartment 20.

FIG. 22 is a cross-sectional view of the structure provided with an array of protrusions 11. The protrusions 11 are deposited on the trace portion 151 of the patterned conductive layer 15 by, for example, electrolytic plating. In this illustration, the protrusions 11 are present in the same quantity and arrangement in every compartment 20, and include electrically conductive posts 111 for vertical electrical connections and thermal pads 113 for device attachment.

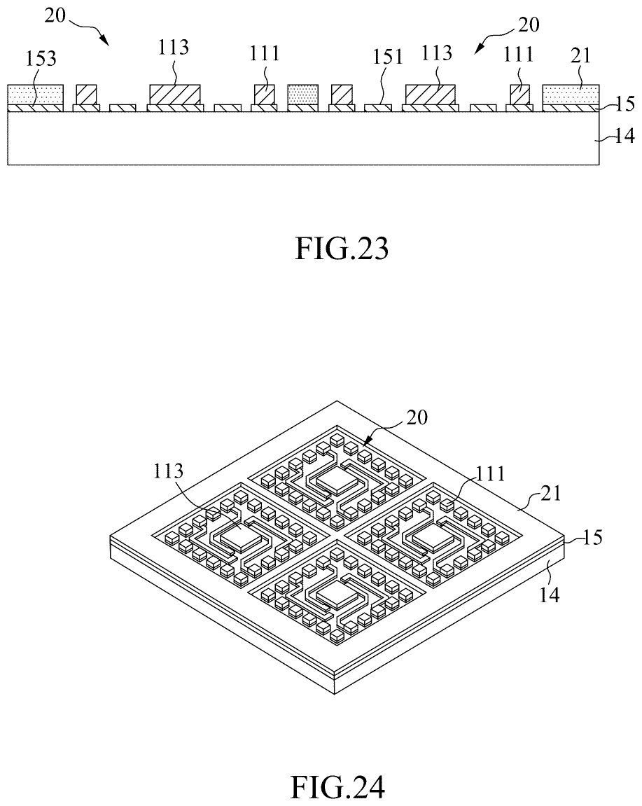

FIGS. 23 and 24 are cross-sectional and top perspective views, respectively, of the structure provided with a crack-inhibiting dielectric frame 21. The crack-inhibiting dielectric frame 21 is deposited on and attached to the top surface of the frame portion 153 of the patterned conductive layer 15. As a result, the compartments 20 are laterally surrounded by the crack-inhibiting dielectric frame 21.

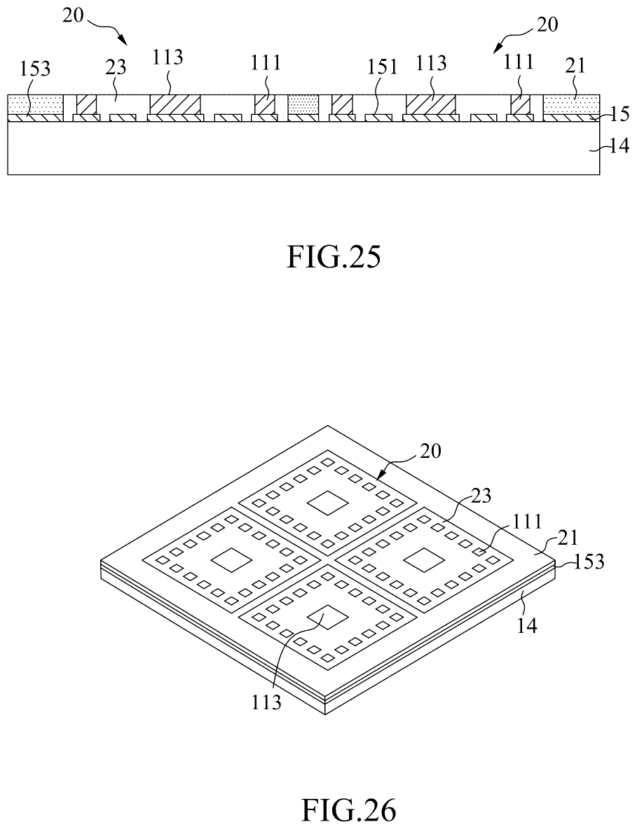

FIGS. 25 and 26 are cross-sectional and top perspective views, respectively, of the structure provided with an interfacial dielectric layer 23. The interfacial dielectric layer 23 is filled into remaining spaces within the compartments 20 to cover sidewalls of the protrusions 11, the unoccupied top surfaces of the sacrificial carrier 14 and the trace portion 151 of the patterned conductive layer 15, and inner peripheries of the crack-inhibiting dielectric frame 21 and the frame portion 153 of the patterned conductive layer 15.

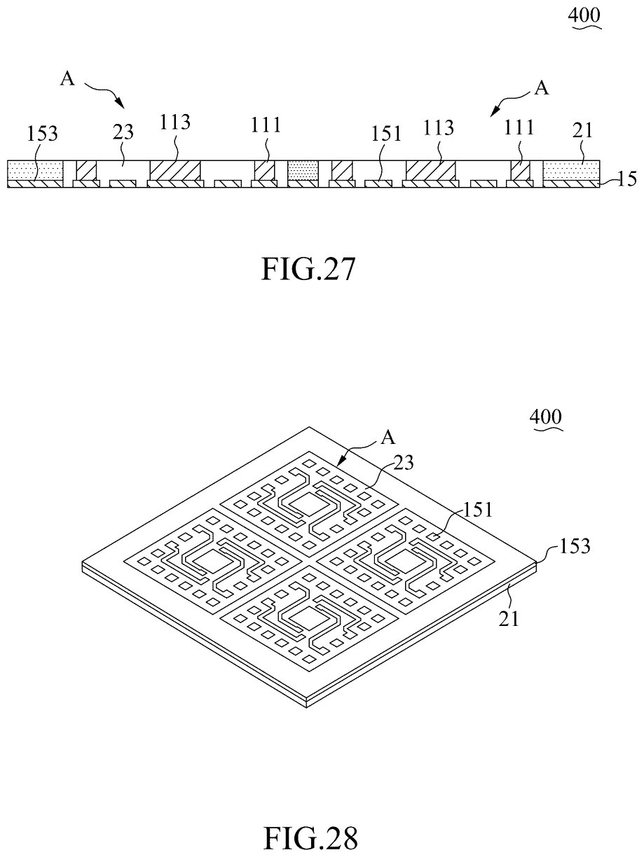

FIGS. 27 and 28 are cross-sectional and bottom perspective views, respectively, of the structure after removal of the sacrificial carrier 14. The sacrificial carrier 14 can be entirely removed by numerous techniques, such as wet chemical etching, electro-chemical etching or laser, to expose the patterned conductive layer 15 from below.

Accordingly, a semiconductor packaging substrate 400 is accomplished and includes the electrically conductive posts 111, the thermal pads 113, the patterned conductive layer 15, the interfacial dielectric layer 23 and the crack-inhibiting dielectric frame 21. The pattered conductive layer 15 is embedded in the interfacial dielectric layer 23 and has a bottom surface substantially coplanar with the bottom surface of the interfacial dielectric layer 23. The electrically conductive posts 111 and the thermal pads 113 are disposed on a top surface of the pattered conductive layer 15 and laterally covered by the interfacial dielectric layer 23.

### Embodiment 5

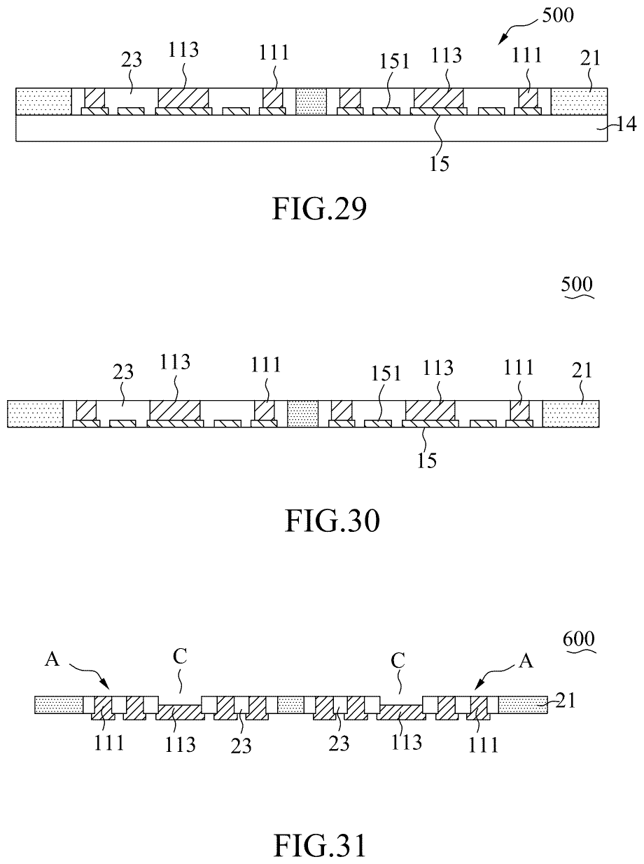

FIGS. 29-30 are schematic views showing a method of making a semiconductor packaging substrate in accordance with the fifth embodiment of the present invention. For purposes of brevity, any description in above Embodiments is incorporated herein insofar as the same is applicable, and the same description need not be repeated.

FIG. 29 is a cross-sectional view of a semiconductor packaging substrate 500 combined with a sacrificial carrier 14. The semiconductor packaging substrate 500 is fabricated on the sacrificial carrier 14 in a similar method as illustrated in FIGS. 20-28, except that the patterned conductive layer 15 includes a trace portion 151 but does not have a frame portion, so the crack-inhibiting dielectric frame 21 is deposited directly onto the sacrificial carrier 14

FIG. 30 is a cross-sectional view of the structure after removal of the sacrificial carrier 14. By removal of the sacrificial carrier 14, the bottom surface of the crack-inhibiting dielectric frame 21 is exposed from below and substantially coplanar with the bottom surfaces of the interfacial dielectric layer 23 and the patterned conductive layer 15.

### Embodiment 6

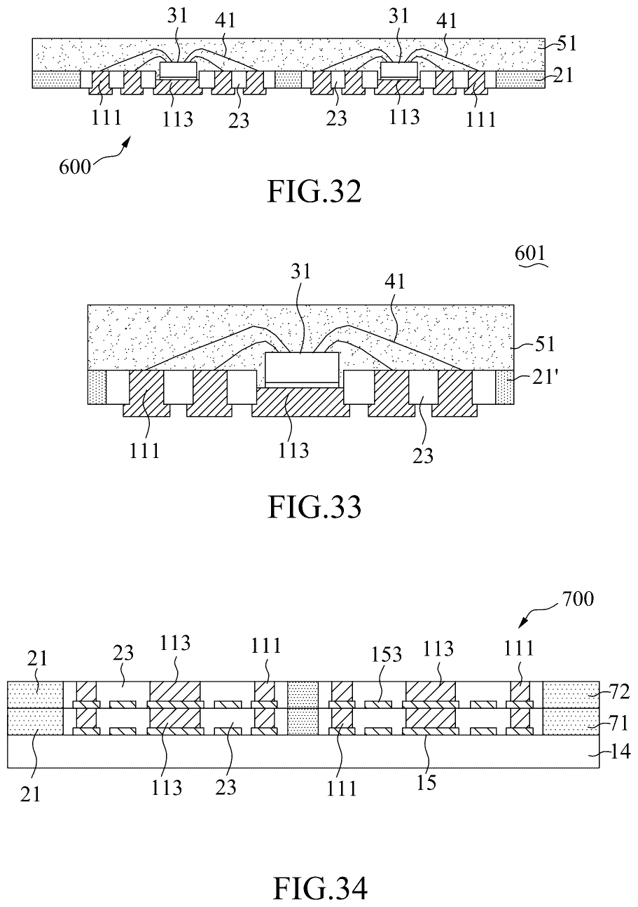

FIGS. 31-32 are schematic views showing a method of making a un-singulated assembly in accordance with the sixth embodiment of the present invention. For purposes of brevity, any description in above Embodiments is incorporated herein insofar as the same is applicable, and the same description need not be repeated.

FIG. 31 is a cross-sectional view of a semiconductor packaging substrate 600 in accordance with the sixth embodiment of the present invention. The semiconductor packaging substrate 600 is similar to that illustrated in FIG. 6, except that the thermal pads 113 are partially removed by, for example, etching from above to form cavities C for device placement. In this illustration, the depth of the cavity C is less than the thickness of the interfacial dielectric layer 23, and the interfacial dielectric layer 23 has inner surrounding sidewalls exposed from the cavities C.

FIG. 32 is a cross-sectional view of the structure provided with semiconductor devices 31 coupled to the semiconductor packaging substrate 600 illustrated in FIG. 31 and optionally with a sealant 51 for encapsulation. Each of the semiconductor devices 31 is disposed in the respective cavity C and mounted on the thermal pad 113 by a thermal adhesive and electrically connected to the electrically conductive posts 111 via wires 41. The sealant 51 covers the semiconductor packaging substrate 600 and the semiconductor devices 31 as well as the wires 41 from above and extends into remaining spaces in the cavities C.

FIG. 33 is a cross-sectional view of a semiconductor assembly 601 singulated from the un-singulated assembly of FIG. 32. The semiconductor assembly 601 includes a crack-inhibiting dielectric sub-frame 21′, electrically conductive posts 111, a thermal pad 113, an interfacial dielectric layer 23, a semiconductor device 31, wires 41 and a sealant 51.

### Embodiment 7

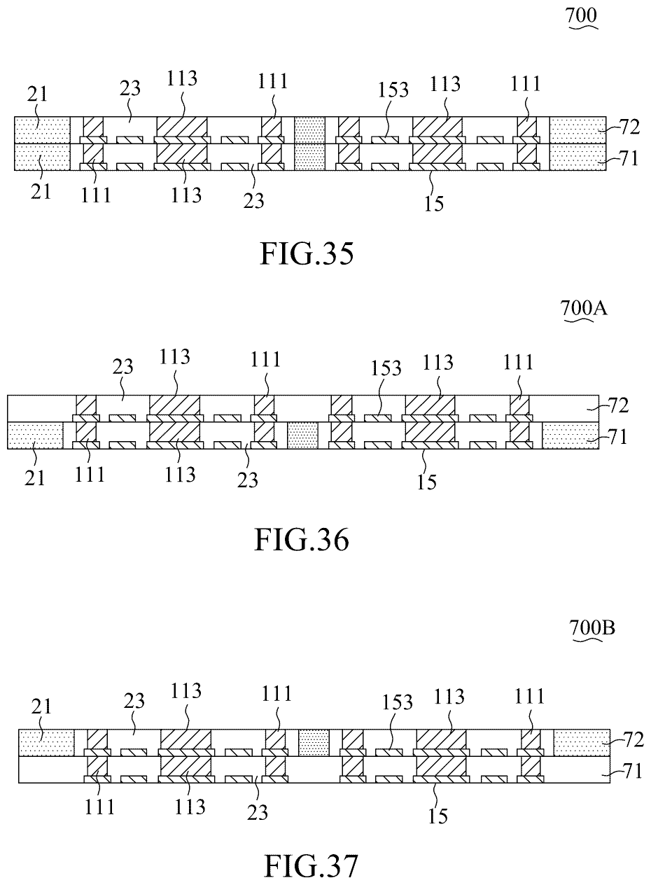

FIGS. 34-35 are schematic views showing a method of making a semiconductor packaging substrate in accordance with the seventh embodiment of the present invention. For purposes of brevity, any description in above Embodiments is incorporated herein insofar as the same is applicable, and the same description need not be repeated.

FIG. 34 is a cross-sectional view of a semiconductor packaging substrate 700 combined with a sacrificial carrier 14. The semiconductor packaging substrate 700 includes a first interconnect component 71 and a second interconnect component 72 in a stacked configuration. The first interconnect component 71 combined with the sacrificial carrier 14 can be first fabricated as illustrated in FIG. 29, and then the patterned conductive layer 15 and the crack-inhibiting dielectric frame 21 of the second interconnect component 72 can be deposited on the first interconnect component 71, followed by forming the electrically conductive posts 111 and the thermal pads 113 and then dispensing the interfacial dielectric layer 23. The crack-inhibiting dielectric frame 21 of the second interconnect component 72 is aligned with and disposed on the crack-inhibiting dielectric frame 21 of the first interconnect component 71. The patterned conductive layer 15 of the second interconnect component 72 extends laterally on the top surface of the interfacial dielectric layer 23 of the first interconnect component 71 and is electrically coupled to the electrically conductive posts 111 and the thermal pads 113 of the first interconnect component 71.

FIG. 35 is a cross-sectional view of the structure after removal of the sacrificial carrier 14. By removal of the sacrificial carrier 14, the crack-inhibiting dielectric frame 21, the patterned conductive layer 15 and the interfacial dielectric layer 23 of the first interconnect component 71 are exposed from below. In this illustration, each of the first interconnect component 71 and the second interconnect component 72 has the same structure as that illustrated in FIG. 30. Although the semiconductor packaging substrate with a stacked structure is illustrated to have two interconnect components in this embodiment, it should be noted that the semiconductor packaging substrate may include additional interconnect components as needed.

FIG. 36 is a cross-sectional view of another aspect of the semiconductor packaging substrate 700A in accordance with the seventh embodiment of the present invention. The semiconductor packaging substrate 700A is similar to that illustrated in FIG. 35, except that the second interconnect component 72 does not include the crack-inhibiting dielectric frame 21.

FIG. 37 is a cross-sectional view of yet another aspect of the semiconductor packaging substrate 700B in accordance with the seventh embodiment of the present invention. The semiconductor packaging substrate 700B is similar to that illustrated in FIG. 35, except that the first interconnect component 71 does not include the crack-inhibiting dielectric frame 21.

The semiconductor packaging substrate and assemblies described above are merely exemplary. Numerous other embodiments are contemplated. In addition, the embodiments described above can be mixed-and-matched with one another and with other embodiments depending on design and reliability considerations. The semiconductor device can share or not share the thermal pad with other semiconductor devices. For instance, a thermal pad can accommodate a single semiconductor device, or numerous semiconductor devices can be mounted over a single thermal pad.

As illustrated in the aforementioned embodiments, a distinctive semiconductor packaging substrate is configured to exhibit improved reliability, in which a plurality of compartments are partitioned by a crack-inhibiting dielectric frame and each accommodate an interconnect unit therein. The interconnect unit mainly includes electrically conductive posts, an interfacial dielectric layer, optionally a thermal pad and optionally a patterned conductive layer. Additionally, the semiconductor packaging substrate may include a plurality of interconnect components in a stacked configuration. In one or more preferred embodiments, each of the interconnect components includes electrically conductive posts, an interfacial dielectric layer, a patterned conductive layer, and optionally a thermal pad, and at least one of the interconnect components further includes a crack-inhibiting dielectric frame which partitions a plurality of compartments to accommodate interconnect units each disposed within a respective one of the compartments and including the electrically conductive posts, the interfacial dielectric layer, the patterned conductive layer, and optionally the thermal pad.

The crack-inhibiting dielectric frame is used instead of the conventionally used metal frame to create a plurality of distinct compartments each accommodating an interconnect unit therein. The top side of the crack-inhibiting dielectric frame may be substantially coplanar with the top sides of the electrically conductive posts, while the bottom side of crack-inhibiting dielectric frame may be located at a level between the top and bottom sides of the electrically conductive posts or substantially coplanar with the bottom sides of the electrically conductive posts or with the bottom surface of the patterned conductive layer adjacent to the bottom sides of electrically conductive posts. Compared to the commonly used metal frame, the crack-inhibiting dielectric frame typically has an elastic modulus lower than 50 Gpa and can reduce warpage caused by the subsequent application of the interfacial dielectric layer. Preferably, the crack-inhibiting dielectric frame is made from a filler-free organic material to prevent filler particles from contributing to the frame's susceptibility to cracking. More preferably, the crack-inhibiting dielectric frame is made of an organic material containing reinforcement configured to suppress crack propagation.

The interfacial dielectric layer covers and contacts and conformally coats sidewalls of the electrically conductive posts and the optional thermal pad as well as inner peripheries of the crack-inhibiting dielectric frame. Typically, the interfacial dielectric layer is made of a different material than the crack-inhibiting dielectric frame and has a bottom surface substantially coplanar with the bottom side of the crack-inhibiting dielectric frame or located at a level below the bottom side of the crack-inhibiting dielectric frame. To effectively absorb stress and mitigate warpage of the structure during the application of the interfacial dielectric layer, this layer may possess an elastic modulus lower than that of the crack-inhibiting dielectric frame. In one or more preferred embodiments, the interfacial dielectric layer is composed of an organic material incorporating electrically insulative fillers with low coefficients of thermal expansion (CTE) to alleviate internal expansion and shrinkage of the interfacial dielectric layer during thermal cycling. For instance, the electrically insulative fillers may have CTE less than 20 ppm.

The electrically conductive posts can provide vertical electrical conduction and are spaced from each other by the interfacial dielectric layer. Typically, the top sides of the electrically conductive posts are substantially coplanar with the top surface of the interfacial dielectric layer. Additionally, the electrically conductive posts may further extend laterally below the bottom surface of the interfacial dielectric layer.

The optional thermal pad can provide thermal conduction with a semiconductor device and is spaced from the electrically conductive posts by the interfacial dielectric layer. The top and bottom sides of the thermal pad may be substantially coplanar with the top and bottom sides of the electrically conductive posts, respectively. Alternatively, in the example of a cavity being formed and aligned with the thermal pad, the top side of the thermal pad is lower than the top side of the electrically conductive post and preferably is located between the top surface and the bottom surface of the interfacial dielectric layer, and the cavity is defined by an inner surrounding sidewall of the interfacial dielectric layer and the top side of the thermal pad as the bottom of the cavity. Additionally, the thermal pad may further extend laterally below the bottom surface of the interfacial dielectric layer. In one or more preferred embodiments, the thermal pad has a foundation and pin fins protruding from the foundation and spaced from each other by gaps. Each of the pin fins has a proximal end adjacent to the foundation and a distal end opposite to the proximal end and substantially coplanar with the top side of each of the electrically conductive posts. The gaps between the pin fins can be filled with the interfacial dielectric layer, so that each of the pin fins has sidewalls laterally covered and surrounded by the interfacial dielectric layer. The distal end of each of the pin fins can be substantially coplanar with the top surface of the interfacial dielectric layer. The distal end of each of the pin fins and the top side of each of the electrically conductive posts preferably have the same exposed surface area. As such, a semiconductor device can be attached onto the foundation, and soldering balls attached to the distal ends of the pin fins and the top sides of the electrically conductive posts for the next-level interconnection can have the same height and thus to avoid false soldering.

The optional patterned conductive layer can be formed adjacent to the bottom sides of the electrically conductive posts to provide horizontal routing. In one and more preferred embodiments, the patterned conductive layer can be first deposited on a sacrificial carrier, followed by deposition of the electrically conductive posts, the optional thermal pads, the crack-inhibiting dielectric frame and the interfacial dielectric layer and then removal of the sacrificial carrier. As a result, the patterned conductive layer can embedded in the interfacial dielectric layer and have a bottom surface substantially coplanar with the bottom surface of the interfacial dielectric layer. For the semiconductor packaging substrate in the stacked configuration, the patterned conductive layer of an upper one of the interconnect components extends laterally over the interfacial dielectric layer of a lower one of the interconnect components and onto the electrically conductive posts and the optional thermal pads of the lower one of the interconnect components.

The present invention also provides a semiconductor assembly, in which semiconductor devices are electrically connected to the above-mentioned semiconductor packaging substrate and optionally encapsulated by a sealant. In one or more preferred embodiments, each of the semiconductor devices is superimposed over and thermally conductible with a respective one of the thermal pads through a thermal adhesive and electrically connected to the electrically conductive posts of the semiconductor packaging substrate through wires. For the semiconductor packaging substrate with a cavity located above the thermal pad, the semiconductor device is disposed in the cavity and laterally surrounded by the surrounding portion of the interfacial dielectric layer. The semiconductor device can be a packaged or unpackaged chip. Furthermore, the semiconductor device can be a bare chip, or a wafer level packaged die, etc.

The term “cover” refers to incomplete or complete coverage in a vertical and/or lateral direction and includes contact and non-contact situations. For instance, in a preferred embodiment, the interfacial dielectric layer partially covers sidewalls of the electrically conductive posts, with their upper sidewalls completely covered by the interfacial dielectric layer and lower sidewalls left uncovered.

The term “surround” refers to relative position between elements regardless of whether the elements are spaced from or adjacent to one another. For instance, in a preferred embodiment, the crack-inhibiting dielectric frame has a plurality of inner peripheries each laterally surrounding a respective one of the interconnect units.

The phrases “mounted over” and “attached on/to/onto” include contact and non-contact with a single or multiple element(s). For instance, in a preferred embodiment, the semiconductor device can be attached on the thermal pad and is separated from the thermal pad by the thermal adhesive.

The phrases “electrical connection”, “electrically connected” and “electrically coupled” refer to direct and indirect electrical connection. For instance, in a preferred embodiment, the semiconductor device is electrically connected to the electrically conductive posts by the wires but does not contact the electrically conductive posts.

The spatially relative terms, such as “top”, “bottom”, “below”, “above”, “lower”, “upper” and the like, may be used herein for ease of description to describe one element or feature's relationship to another element(s) or feature(s) as illustrated in the figures. The spatially relative terms are intended to encompass different orientations of the substrate or assembly in use or operation in addition to the orientation depicted in the figures. For example, if the substrate or assembly in the figures is turned over, elements described as “below” other elements or features would then be oriented “above” the other elements or features, and “bottom” surfaces would become “top” surfaces. Thus, the example term “below” can encompass both an orientation of above and below. The substrate or assembly may be otherwise oriented (rotated 90 degrees or at other orientations) and the spatially relative descriptions used herein interpreted accordingly.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A semiconductor packaging substrate, comprising a crack-inhibiting dielectric frame and a plurality of interconnect units each disposed within a respective one of separate compartments defined by the crack-inhibiting dielectric frame, each of the interconnect units including electrically conductive posts and an interfacial dielectric layer, wherein:
the crack-inhibiting dielectric frame has a plurality of inner peripheries each laterally surrounding a respective one of the interconnect units;
the electrically conductive posts are disposed within the compartments and spaced from each other by the interfacial dielectric layer; and
the interfacial dielectric layer laterally covers and surrounds sidewalls of the electrically conductive posts and coats the inner peripheries of the crack-inhibiting dielectric frame.

2. The semiconductor packaging substrate of claim 1, wherein the crack-inhibiting dielectric frame has an elastic modulus lower than 50 Gpa.

3. The semiconductor packaging substrate of claim 1, wherein the crack-inhibiting dielectric frame is an organic material with a reinforcement configured to suppress crack propagation.

4. The semiconductor packaging substrate of claim 1, wherein the interfacial dielectric layer has an elastic modulus lower than that of the crack-inhibiting dielectric frame.

5. The semiconductor packaging substrate of claim 1, wherein the interfacial dielectric layer is an organic material with electrically insulative fillers.

6. The semiconductor packaging substrate of claim 5, wherein the electrically insulative fillers have a coefficient of thermal expansion (CTE) less than 20 ppm.

7. The semiconductor packaging substrate of claim 1, wherein the electrically conductive posts further extend laterally below a bottom surface of the interfacial dielectric layer.

8. The semiconductor packaging substrate of claim 1, wherein each of the interconnect units further includes a patterned conductive layer adjacent to the electrically conductive posts.

9. The semiconductor packaging substrate of claim 8, wherein the patterned conductive layer is embedded in the interfacial dielectric layer and has a bottom surface substantially coplanar with a bottom surface of the interfacial dielectric layer.

10. The semiconductor packaging substrate of claim 1, wherein each of the interconnect units further includes a thermal pad, and the interfacial dielectric layer laterally covers and surrounds sidewalls of the thermal pad.

11. The semiconductor packaging substrate of claim 10, wherein the thermal pad has a top side as a bottom of a cavity, and wherein the interfacial dielectric layer laterally surrounds the cavity.

12. The semiconductor packaging substrate of claim 10, wherein the electrically conductive posts and the thermal pad further extend laterally below a bottom surface of the interfacial dielectric layer.

13. The semiconductor packaging substrate of claim 10, wherein each of the interconnect units further includes a patterned conductive layer adjacent to the electrically conductive posts and the thermal pad.

14. The semiconductor packaging substrate of claim 13, wherein the patterned conductive layer is embedded in the interfacial dielectric layer and has a bottom surface substantially coplanar with a bottom surface of the interfacial dielectric layer.

15. The semiconductor packaging substrate of claim 10, wherein the thermal pad has a foundation and pin fins protruding from the foundation and spaced from each other by gaps.

16. The semiconductor packaging substrate of claim 15, wherein each of the pin fins has a proximal end adjacent to the foundation and a distal end opposite to the proximal end and substantially coplanar with an exposed surface of each of the electrically conductive posts, and the exposed surface of each of the electrically conductive posts has an area substantially equal to an exposed surface area of the proximal end of the pin fin.

17. The semiconductor packaging substrate of claim 15, wherein the interfacial dielectric layer further fills the gaps and laterally covers and surrounds sidewalls of the pin fins.
